(19) United States
(12) Patent Application Publication
(10) Pub. No.: US 2009/0296349 A1
(43) Pub. Date: Dec. 3, 2009

(54) COMPONENT-EMBEDDED PRINTED CIRCUIT BOARD, METHOD OF MANUFACTURING THE SAME, AND ELECTRONIC APPARATUS INCLUDING THE SAME

(75) Inventor: Daigo SUZUKI, Yokohama-shi (JP)

Correspondence Address: KNOBBE MARTENS OLSON & BEAR LLP, 2040 MAIN STREET, FOURTEENTH FLOOR, IRVINE, CA, 92614, US

(73) Assignee: Kabushiki Kaisha Toshiba, Tokyo (JP)

(21) Appl. No.: 12/427,567

(22) Filed: Apr. 21, 2009

(30) Foreign Application Priority Data
May 29, 2008 (JP) 2008-141482

(51) Int. Cl. H05K 7/20; H05K 3/46

(52) U.S. Cl. 361/705; 361/707; 29/830

(57) ABSTRACT

According to one embodiment, a component-embedded printed circuit board includes an opening for member fixation provided on part of a peripheral edge of an outer layer side of the first substrate, a metal member for heat radiation laminated to outer layer side, except for the opening for member fixation, of the first substrate with an insulating layer therebetween, a through-hole penetrating the first and second substrates and communicating with the opening for member fixation, and a through-hole conductor provided on an internal wall of the through-hole.

### CROSS-REFERENCE TO RELATED APPLICATIONS

This application is based upon and claims the benefit of priority from Japanese Patent Application No. 2008-141482, filed May 29, 2008, the entire contents of which are incorporated herein by reference.

### BACKGROUND

1. Field

One embodiment of the invention relates to a component-embedded printed circuit board with built-in electronic components, a method of manufacturing the same, and an electronic apparatus including the same.

2. Description of the Related Art

Small electronic apparatuses, such as portable computers, mobile terminals, etc., require a technique for component mounting on boards that enable high-density wiring with high circuit design flexibility to meet the requirements for thinner, shorter configurations. There is a laminated printed circuit board that is embedded with some circuit components in its inner layer in order to ensure high-density wiring. This component-embedded printed circuit board, having the circuit components embedded in its inner layer, needs a heat radiation measure to counter heat generation by the built-in components.

A heat radiation technique for built-in components in one such component-embedded printed circuit board is described in, for example, Jpn. Pat. Appln. KOKAI Publication No. 2004-327624. According to this technique, heat generated by the built-in components is conducted to the plate for heat radiation outside the board through a heat conduction via.

The component-embedded printed circuit board described above has metal for heat radiation on the outermost layer of the printed circuit board, thereby further increasing radiation of heat generated by the built-in components. However, the structure of this printed circuit board with the metal for heat radiation is a laminated structure in which the metal for heat radiation is provided on the outermost layer. Therefore, it is impossible to obtain a connection area sufficient for the formation of external connection electrodes capable of stably supplying a strong electric current, as in a power source circuit.

### BRIEF DESCRIPTION OF THE SEVERAL VIEWS OF THE DRAWINGS

A general architecture that implements the various feature of the invention will now be described with reference to the drawings. The drawings and the associated descriptions are provided to illustrate embodiments of the invention and not to limit the scope of the invention.

FIG. 1 is an exemplary sectional view showing the configuration of a component-embedded printed circuit board according to a first embodiment of the invention;

FIG. 2 is an exemplary perspective view showing the configuration of the bottom of the component-embedded printed circuit board according to the first embodiment;

FIG. 3 is an exemplary sectional view showing an example where the component-embedded printed circuit board according to the first embodiment is mounted;

FIG. 4 is an exemplary sectional view showing another example where the component-embedded printed circuit board according to the first embodiment is mounted;

FIG. 5 is an exemplary sectional view showing a step of a manufacturing process for the component-embedded printed circuit board according to the first embodiment;

FIG. 6 is an exemplary sectional view showing another step of the manufacturing process of the component-embedded printed circuit board;

FIG. 7 is an exemplary sectional view showing another step of the manufacturing process of the component-embedded printed circuit board;

FIG. 8 is an exemplary sectional view showing another step of the manufacturing process of the component-embedded printed circuit board;

FIG. 9 is an exemplary sectional view showing another step of the manufacturing process of the component-embedded printed circuit board;

FIG. 10 is an exemplary sectional view showing another step of the manufacturing process of the component-embedded printed circuit board;

FIG. 11 is an exemplary sectional view showing another step of the manufacturing process of the component-embedded printed circuit board;

FIG. 12 is an exemplary sectional view showing another step of the manufacturing process of the component-embedded printed circuit board;

FIG. 13 is an exemplary sectional view showing another step of the manufacturing process of the component-embedded printed circuit board;

FIG. 14 is an exemplary perspective view showing the configuration of the electronic apparatus according to a second embodiment of the invention;

FIG. 15 is an exemplary perspective view showing the configuration of the inside of the electronic apparatus according to the second embodiment; and

FIG. 16 is an exemplary view showing the configuration of the main part of the electronic apparatus according to the second embodiment.

### DETAILED DESCRIPTION

Various embodiments according to the invention will be described hereinafter with reference to the accompanying drawings. In general, according to one embodiment of the invention, there is provided a component-embedded printed circuit board comprising: a first substrate having a component mounting surface on an inner layer side thereof; a second substrate laminated to the first substrate with an insulating layer therebetween; a built-in component mounted on the component mounting surface and covered by the insulating layer; an opening for member fixation provided on part of a peripheral edge of an outer layer side of the first substrate; a metal member for heat radiation laminated to outer layer side, except for the opening for member fixation, of the first substrate with an insulating layer therebetween; a through-hole penetrating the first and second substrates and communicating with the opening for member fixation; and a through-hole conductor provided on an internal wall of the through-hole.

The component-embedded printed circuit boards according to the following embodiments are applicable to various multilayer printed circuit boards including an arbitrary number of layers. For ease of illustration, however, a multilayer printed circuit board is given as an example in which two substrates, having electrically-conductive layers formed on their opposite sides, individually, are laminated to each other with an insulating layer between them, thereby realizing a four-layer wiring. In a laminated structure based on first and second substrates, according to each of the embodiments, conductor layers that are formed on the lamination side of one another are referred to as inside conductor layers, and an exposed conductor layer (outermost layer) on the surface layer side as an outside conductor layer.

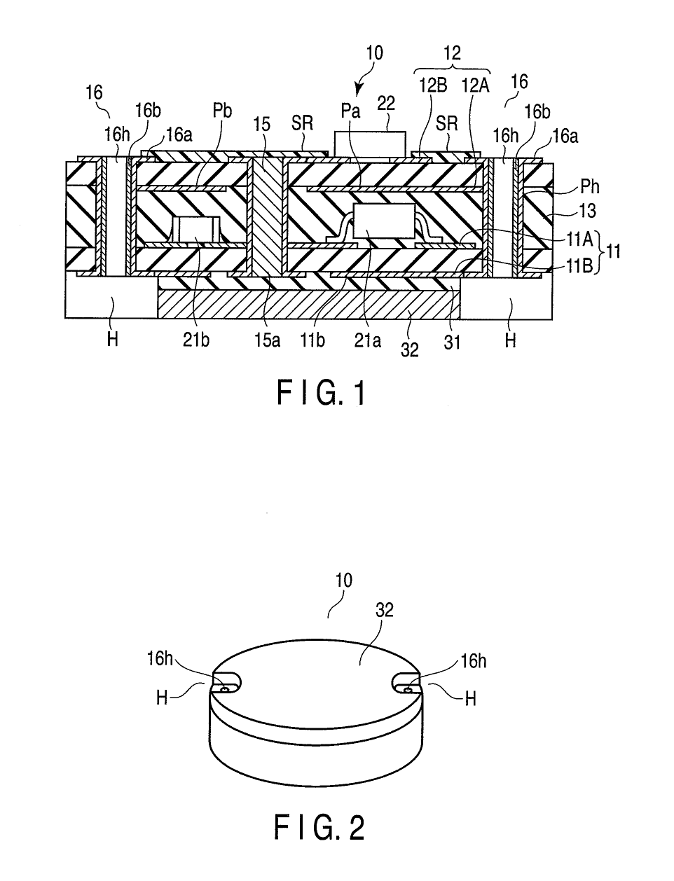

As shown in FIGS. 1 and 2, the component-embedded printed circuit board according to the first embodiment of the invention includes: a first substrate 11; a second substrate 12 laminated to the first substrate 11 with an insulating layer 13 therebetween; built-in components 21a and 21b mounted on the inside conductor layer 11A (serving as a component mounting surface) of the first substrate 11 and covered by the insulating layer 13; openings H for member fixation provided on parts of the peripheral edge of the external layer of the first substrate 11; a metal member 32 for heat radiation laminated to the external layer (except for the openings H for member fixation) of the first substrate 11 with the insulating layer 31 therebetween; through-holes Ph penetrating the first and second substrates 11 and 12 and communicating with the corresponding openings H for member fixation; and through-hole conductors 16a and 16b forming a two-layer structure and provided on the internal wall of each of the through-holes Ph.

The through-hole conductors 16a and 16b and a through-hole 16h defined by the internal face of the through-hole conductor 16b constitutes a corresponding external connection electrode 16.

The through-hole conductors 16a and 16b forming the two-layer structure are each formed by a cylindrical conductive member. The cylindrical conductive member constitutes an electrode lead for the corresponding external connection electrode 16. In this embodiment, the through-hole conductor 16a at the outer layer side is formed from a metal plated cylindrical conductive member, and the through-hole conductor 16b at the internal layer side is formed from a bored conductor. This through-hole conductor 16b is formed in the following manner: a conductor (e.g., a conductive resin containing metal particles) that can be joined by solder is embedded in the through-hole conductor 16a and a hole of predetermined diameter is bored in the embedded conductor lengthwise along the through-hole conductor 16a. Accordingly, the through-hole conductor 16b forms a cylindrical conductive member with a wall of constant thickness along the internal face of the through-hole conductor 16a. Instead of the embedded conductor (i.e., the conductive resin) mentioned above, the through-hole conductor 16b may be formed from an embedded conductor plated with metal, for example. In this embodiment, the through-hole conductors form a two-layer structure. However, the through-hole conductor 16b may be used alone, by omitting the metal plated through-hole conductor 16a. The internal face of the through-hole conductor 16b forms a solder joint face. In addition, the internal face of the through-hole conductor 16b defines the through-hole 16h through which a fixing member extends for mounting the component-embedded printed circuit board 10 on an external mounting mother body. The external mounting mother body on which the component-embedded printed circuit board 10 is mounted is, for example, an external mounting housing (i.e., apparatus housing) or a parent substrate (i.e., motherboard). Fixing members for mounting the printed circuit board 10 are, for example, fastening screws or rod-like terminal pins.

As shown in FIG. 2, each of the openings H for member fixation is formed by cutting away part of the peripheral edges of the insulating layer 31 and metal member 32 for heat radiation on the outer layer side of the first substrate 11 by use of, for example, a drill pit. Each of the openings H for member fixation is in the form of, for example, a horseshoe-shaped notch. The mounting portion H communicates with the through-hole 16h of the corresponding external connection electrode 16. The open end of the through-hole 16h is exposed almost in the middle of the bottom of the horseshoe-shaped notch.

The first substrate 11 includes the inside conductor layer 11A and the outside conductor layer 11B. The inside conductor layer 11A serves as a component mounting surface. The inside conductor layer 11A, which serves as a component mounting surface, has a component mounting pad for mounting the built-in components 21a and 21b thereon. On the component mounting pad are the built-in components 21a and 21b that generate heat during operation. Formed on the outside conductor layer 11B is a wiring layer (i.e., copper foil pattern layer). In addition, formed on the outside conductor layer 11B is an outer-surface solid pattern layer 11b for heat radiation by which heat generated from the built-in components 21a and 21b is conducted to a metal member 32 for heat radiation. The metal member 32 for heat radiation (e.g., metal plate for heat radiation) is laminated to the outside conductor layer 11B of the first substrate 11 with the insulating layer 31 (formed from, e.g., glass epoxy resin) therebetween.

The second substrate 12 includes an inside conductor layer 12A and an outside conductor layer 12B. The inside conductor layer 12A forms a wiring layer (i.e., copper foil pattern layer). The inside conductor layer 12A has interior pattern layers Pa and Pb for heat radiation of predetermined shape and area so as to cover the built-in components 21a and 21b, respectively, mounted on the first substrate 11. In the first embodiment, solid pattern layers that cover the entire corresponding areas in which the built-in components 21a and 21b are mounted via the insulating layer 13 are used as the interior pattern layers Pa and Pb for heat radiation. The outside conductor layer 12B forms a component mounting surface. In addition, the outside conductor layer 12B has a component mounting pad for mounting an built-in component 22 on the surface thereof. The surface-mounting built-in component 22 is mounted on the component mounting pad. A solder resisting film (SR) is formed in a specific area of the outside conductor layer 12B of the second substrate 12 on which the surface-mounting built-in component 22 is mounted.

Near the places where the built-in components 21a and 21b are mounted is a through-hole 15 penetrating the first substrate 11 and the second substrate 12 and filled with a conductive resin 15a. The through-hole 15 serves as a heat radiation passage for the built-in components 21a and 21b and the circuit wiring.

The metal member 32 for heat radiation (e.g., metal plate for heat radiation) is laminated to the outside conductor layer 11B of the first substrate 11 with a glass epoxy resin (i.e., the insulating layer 31) therebetween by pressing work, for example, and is thus integrated with the body of the printed circuit board. The insulating layer 31 has a thickness of approximately 60 μm for example, and forms a heat conduction path between the outer-surface solid pattern layer 11b for heat radiation and the metal member 32 for heat radiation.

Heat generated by the built-in components 21a and 21b is conducted to the metal member 32 for heat radiation via the external connection electrodes 16 and through-hole 15. Specifically, heat generated by the built-in components 21a and 21b is conducted to the outer-surface solid pattern layer 11b for heat radiation via the interior pattern layers Pa and Pb for heat radiation and via the external connection electrodes 16 or through-hole 15, and is further conducted to the metal member 32 for heat radiation via the insulating layer 31. Other than these heat conduction paths, heat generated by the built-in components 21a and 21b is conducted to the outer-surface solid pattern layer 11b for heat radiation via the through-hole 15 and is further conducted to the metal member 32 for heat radiation via the insulating layer 31.

Accordingly, on account of the heat radiation structure in which the metal member 32 for heat radiation is formed as the outermost layer, heat generated by the built-in components 21a and 21b is efficiently radiated outside.

Operating power source is supplied to the built-in components 21a and 21b via the external connection electrodes 16. Each of the external connection electrodes 16 has an electrode structure in which a hole is bored perpendicular to the direction of the lamination. This ensures a connection area (i.e., solder joint face) sufficient for an external connection and thereby provides the configuration of an external connection circuit that is highly reliable and stable. In addition, each of the electrode leads is constituted by the through-hole conductors 16a and 16b forming the two-layer structure. This ensures the mounting and connecting structure such that the printed circuit board is rigidly fixed to the mounting mother body and electric current flows easily. Accordingly, high reliability of mounting and stability of circuit operation can be assured. Further, as described above, each of the external connection electrodes 16 form heat radiation passages that are highly heat conductive and the heat from built-in components 21a and 21b is efficiently conducted to the metal member 32 for heat radiation.

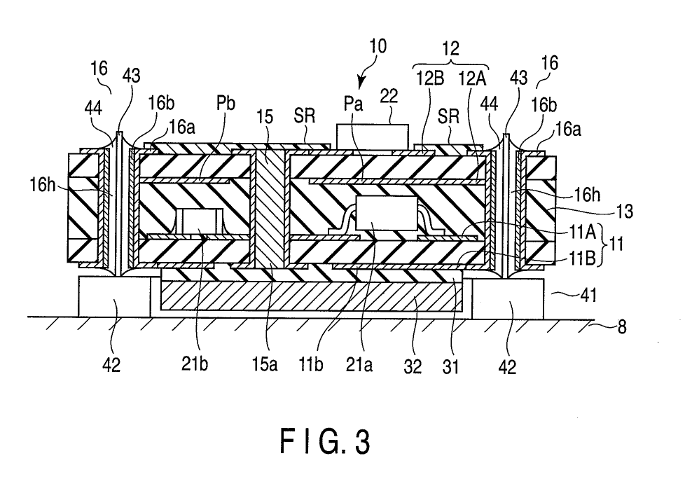

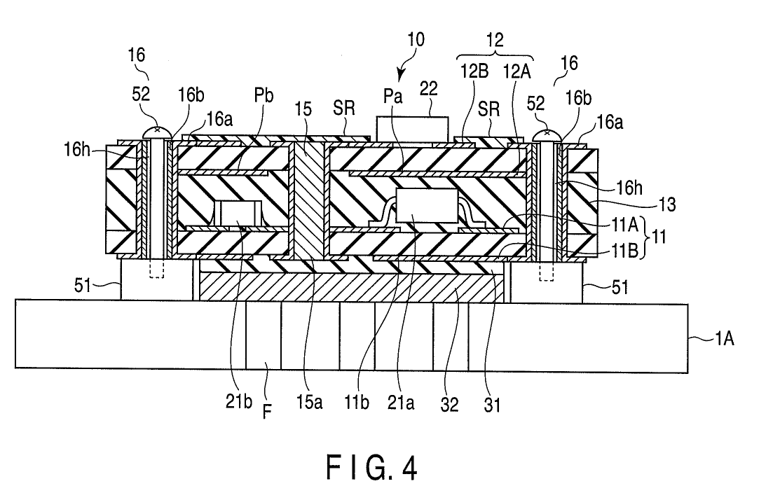

FIGS. 3 and 4 show examples where the component-embedded printed circuit board 10 with external connection electrodes 16 of the above-described through-hole structure is mounted on the mounting mother body. FIG. 3 is an example where a parent board (i.e., motherboard) 8 is used as a mounting mother body, and FIG. 4 is an example where an apparatus housing 1A is used as a mounting mother body.

As shown in FIG. 3, in the mounting structure where the motherboard 8 is used as a mounting mother body, daughterboard mounting areas of the motherboard 8 have daughterboard mounting members 41 so as to correspond to the component-embedded printed circuit board 10 to be mounted. Each of the daughterboard mounting members 41 is provided with a daughterboard connection electrode 42 so as to correspond with the external connection electrode 16. Further, a connection pin (i.e., lead terminal) 43 extends upward from the daughterboard connection electrode 42 so as to correspond to the through-hole 16h.

The procedure for mounting the component-embedded printed circuit board 10 on the motherboard 8 is described below. In a component mounting step, the through-holes 16h of the component-embedded printed circuit board 10 to be mounted are aligned to the corresponding connection pins 43 extending upwards from the daughterboard connection electrodes 42 of the daughterboard mounting members 41. Then, the connection pins 43 are extended through the corresponding through-holes 16h, thereby placing the component-embedded printed circuit board 10 on the daughterboard mounting members 41. Subsequently, in a reflow step, molten solder 44 is caused to flow into the through-holes 16h. Consequently, the through-holes 16h are filled with the solder 44 and the connection pins 43 are soldered to the through-holes 16h. Thus, the component-embedded printed circuit board 10 is mounted on the daughterboard mounting area of the motherboard 8, and the component-embedded printed circuit board 10 is connected in circuit to the motherboard 8 via the external connection electrodes 16. In this circuit connection, each of the external connection electrodes 16 has an electrode structure bored perpendicular to the lamination. This ensures a connection area (solder joint face) sufficient for external connection, and hence the configuration of an external connection circuit that is highly reliable and stable. In addition, each of the electrode leads is constituted by the through-hole conductors 16a and 16b forming a two-layer structure. This ensures the mounting and connecting structure such that the printed circuit board is rigidly fixed to the mounting mother body and electric current flows easily. Accordingly, high reliability of mounting and stability of circuit operation can be assured.

As shown in FIG. 4, the mounting structure that uses as a mounting mother body the housing 1A of an electronic apparatus is provided with studs 51 that have screw portions for fastening screws 52 so as to correspond to the external connection electrodes 16 of a component-embedded printed circuit board 10 to be mounted on the substrate mounting area of the housing 1A. The component-embedded printed circuit board 10 is placed on the studs 51, and fastening screws 52 are inserted into the corresponding through-holes 16h and screwed into and fastened to the screw portions of the studs 51. Consequently, the component-embedded printed circuit board 10 is mounted on the substrate mounting area of the housing 1A. In the mounting example shown in FIG. 4, the substrate mounting area of the housing 1A has cooling-air channels F for use as the heat radiation paths of a metal member 32 for head radiation. In this mounting structure, the screw portions of the studs 51 are used as, for example, power source supply terminals for the component-embedded printed circuit board 10, thereby forming a power supply path of great current capacity. In addition, since electrode pads are provided on the component mounting surfaces (i.e., upper faces) of the studs 51, the end faces of through-hole conductors 16a and 16b of each of the external connection electrodes 16 are provided in face-contact with the corresponding electrode pad, thereby forming a power source supply path of great current capacity. Thus, even in a configuration in which the component-embedded printed circuit board 10 is mounted on the studs 51, sufficient connection areas (solder joint faces) can be assured by the external connection electrodes 16. This ensures the configuration of an external connection circuit that is highly reliable and stable. In addition, each of the electrode leads is constituted by the through-hole conductors 16a and 16b forming a two-layer structure. This ensures a mounting and connecting structure such that the printed circuit board is rigidly fixed to the mounting mother body and electric current flows easily. Accordingly, high reliability of mounting and stability of circuit operation can be assured. In this embodiment described above, each of the external connection electrodes 16 of the component-embedded printed circuit board 10 may be applicable not only to supply power source but also to connect various circuits externally.

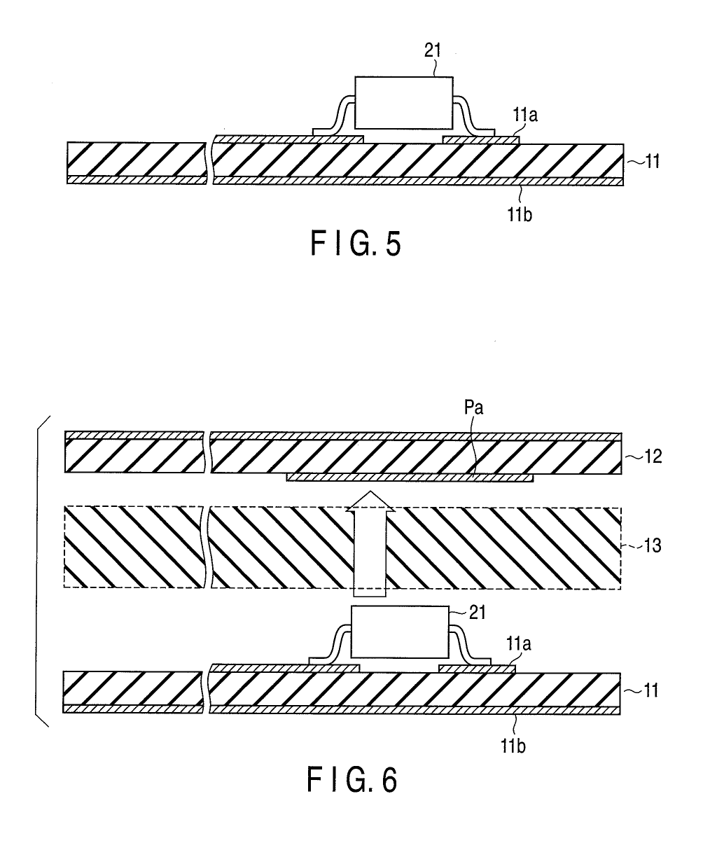

Referring to FIGS. 5 to 11, next will be described a process for manufacturing the component-embedded printed circuit board 10 according to the first embodiment described above, which has external connection electrodes 16, each of which is of the through-hole form.

In step 1 shown in FIG. 5, an electronic component 21, which is an built-in component, is mounted on the component mounting pad 11a of the first substrate 11. Outer-surface solid pattern layer 11b for heat radiation is formed on the outside conductor layer of the first substrate 11.

In step 2 shown in FIG. 6, the second substrate 12 is laminated to the first substrate 11 with an insulating layer 13 therebetween by press working. An interior pattern layer Pa for heat radiation is formed in the inside conductor layer of the first substrate 11.

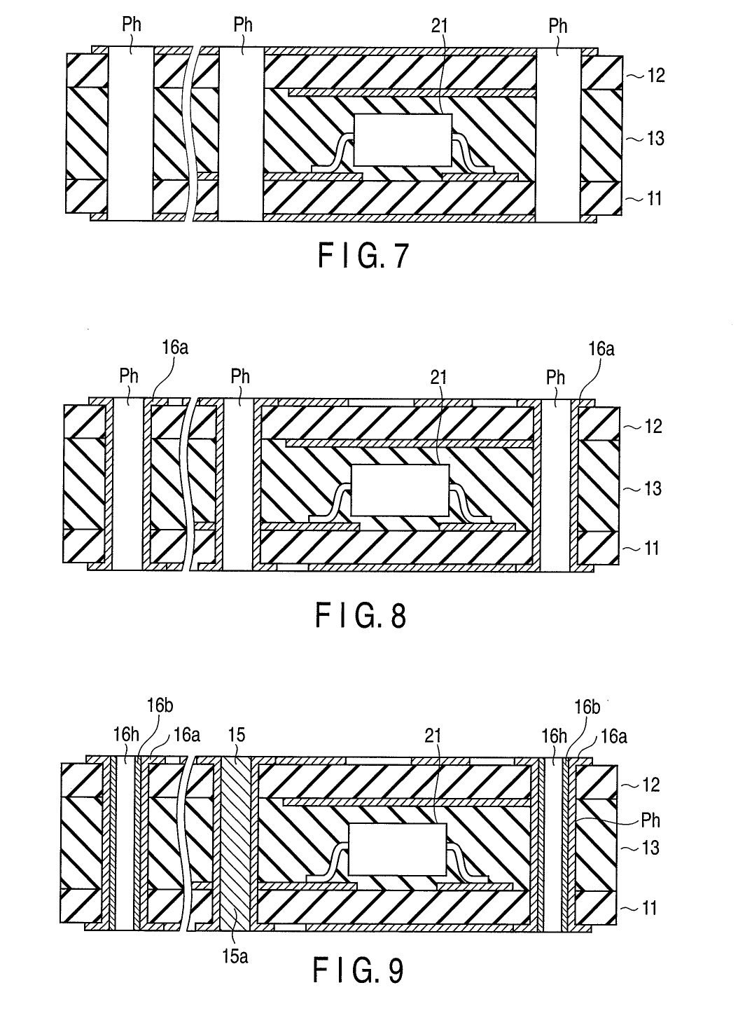

In step 3 shown in FIG. 7, a boring step such as laser boring or drilling is performed to bore through-holes, via holes, and suchlike in the printed circuit board body in which the first and second substrates 11 and 12 are provided in layers. In step 3, in addition to a hole Ph for a through-hole 15, holes Ph for the external connection electrodes 16 are also bored.

In step 4 shown in FIG. 8, the holes are plated and an outer surface is patterned. In this step 4, in addition to the hole Ph for the through-hole 15, the holes Ph for the external connection electrodes 16 are also plated with metal (e.g., copper), thus forming outer layer side through-hole conductors 16a in the holes Ph of the corresponding external connection electrodes 16.

In step 5 shown in FIG. 9, the hole Ph used as the through-hole 15 and the holes Ph used for the external connection electrodes 16 are filled with a conductive resin containing metal particles. Further, a hole of predetermined diameter is made through the conductive resin in each of the holes Ph (which are used for the external connection electrodes 16) lengthwise as in the corresponding through-hole conductor 16a; thus a cylindrical through-hole conductor 16b of predetermined wall thickness is formed on the internal face of the corresponding through-hole conductor 16a. The hole Ph for use as the through-hole 15 is kept filled with the conductive resin 15a.

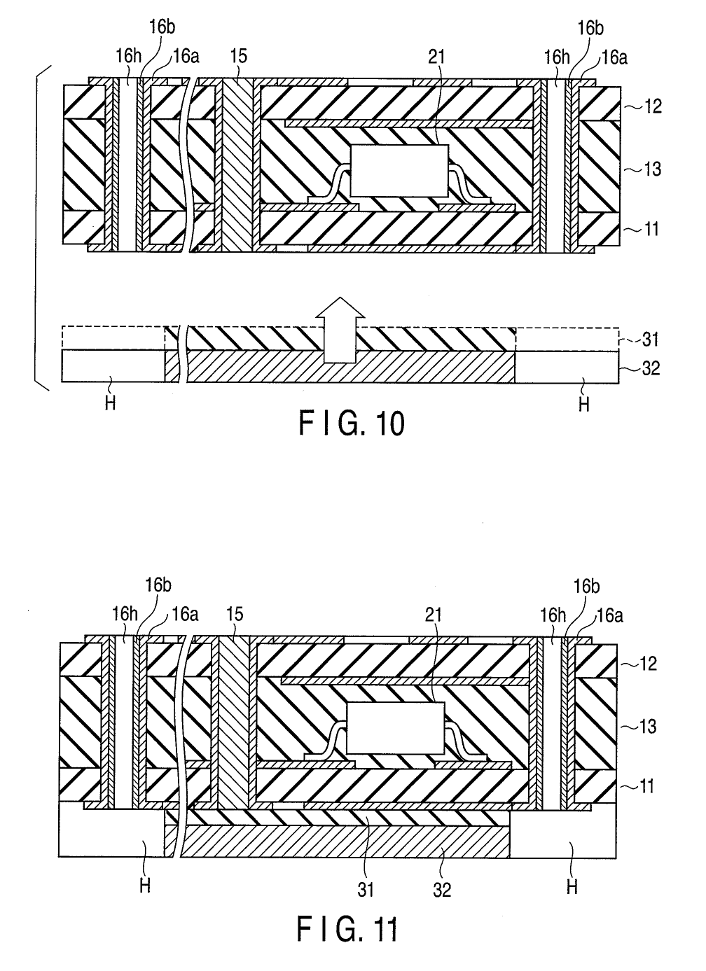

In step 6 shown in FIG. 10, a metal member 32 for heat radiation is bonded to the printed circuit board body via an insulating layer 31 formed of glass epoxy resin through press working. Thereby, the metal member 32 for heat radiation and the printed circuit board body are integrated in layers. The thickness of the insulating layer (glass epoxy resin) 31 and that of the metal member 32 for heat radiation may be, for example, about 60 μm and 1 mm respectively. Openings H for member fixation in the form of horseshoe-shaped notches, as shown in FIG. 2, are pre-formed in the metal member 32 for heat radiation to be layered in the printed circuit board body. Using a drill pit for example, the openings H for member fixation are defined by forming the horseshoe-shaped notches by cutting work in areas (e.g., two opposite areas on the circumference) of the peripheral edge of the metal plate (i.e., disk-like substrate), which forms the material of the metal member 32 for heat radiation.

As a result of press working in the step 6 described above, component-embedded printed circuit board 10 as shown in FIG. 11 is manufactured, which has the external connection electrodes 16, each having a two-layer conductor structure such that the open end of the through-hole 16h (i.e., mounting hole) is exposed almost in the middle of the bottom of the horseshoe-shaped notch of the corresponding mounting portion H.

In the foregoing process of manufacturing the component-embedded printed circuit board 10, the metal member 32 for heat radiation is bonded to the printed circuit board body in layers after the through-holes 16h for the external connection electrodes 16 are bored. However, the invention is not limited to the steps described above. For example, after the metal member 32 for heat radiation is bonded to the printed circuit board body in layers, the through-holes 16h may be bored for the external connection electrodes 16.

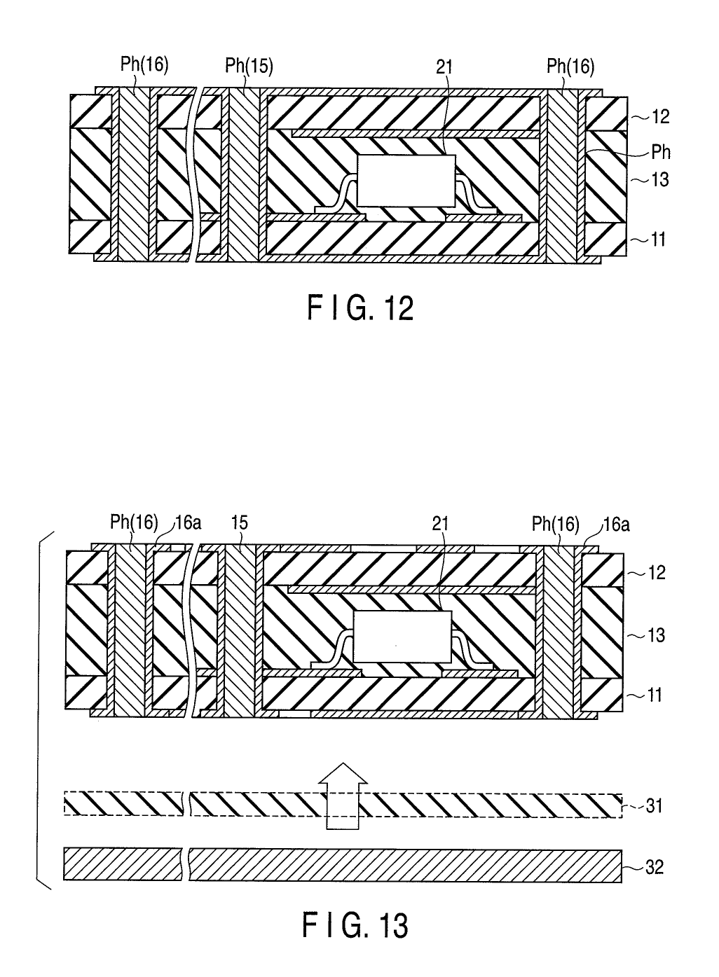

In this example, in the step 4 shown in FIG. 8, the hole Ph used as the through-hole 15 and the holes Ph used for the external connection electrodes 16 are plated with metal (e.g., copper) and then, in the step 5 shown in FIG. 12, the holes Ph for through used as the through-hole 15 and the holes Ph used for the external connection electrodes 16 are filled with a conductive resin containing metal particles. In FIG. 12, Ph (15) and Ph (16) represent the hole used as the through-hole 15 and the holes used for external connection electrodes 16, respectively.

Subsequently, the step 6 shown in FIG. 13 is performed including the external layer-patterning step, the metal plate pressing step, mounting portion H formation step, and through-hole conductor 16b formation step.

Specifically, in the external layer-patterning step, a patterned external layer is formed on the printed circuit board body in which the first and second substrates 11 and 12 are arranged in layers.

In the metal plate pressing step, a metal member 32 for heat radiation is bonded to the printed circuit board body via an insulating layer 31 such that the printed circuit board body and metal member 32 for heat radiation are integrated in layers. The metal member 32 for heat radiation bonded to the printed circuit board body is a metal plate (i.e., disk-like substrate) in which openings H for member fixation have not yet been formed. That is, the metal plate forms the material of the metal member 32 for heat radiation.

In the mounting portion H formation step, openings H for member fixation are formed by forming horseshoe-shaped notches by cutting work in the disk-like substrate by means of, for example, a drill pit (see FIGS. 2 and 10).

In the through-hole conductor 16b formation step, a hole of predetermined diameter is made through the conductive resin in each of the holes Ph (16) (which are used for the external connection electrodes 16) lengthwise as in the corresponding through-hole conductor 16a. Thereby, a cylindrical through-hole conductor 16b with a wall of predetermined thickness is formed on the internal face of the through-hole conductor 16a, and a through-hole 16h for use as a mounting hole is defined by the internal face of the through-hole conductor 16b (see FIGS. 9 to 11).

Thus, as shown in FIG. 11, a component-embedded printed circuit board 10 is manufactured, which has the external connection electrodes 16, each having a two-layer conductor structure such that the open end of the through-hole 16h (i.e., mounting hole) is exposed almost in the middle of the bottom of the horseshoe-shaped notch of the corresponding mounting portion H.

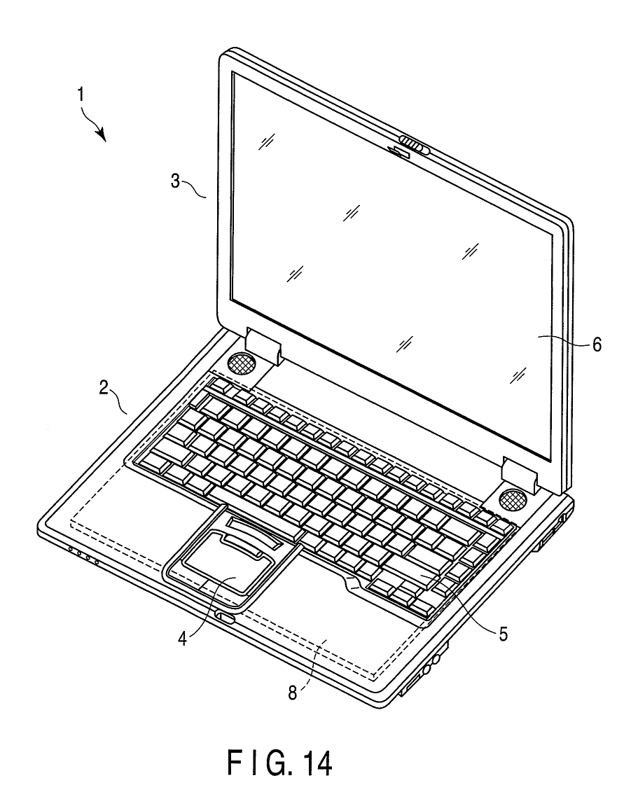

A second embodiment according to the invention will now be described with reference to FIGS. 14 to 16.

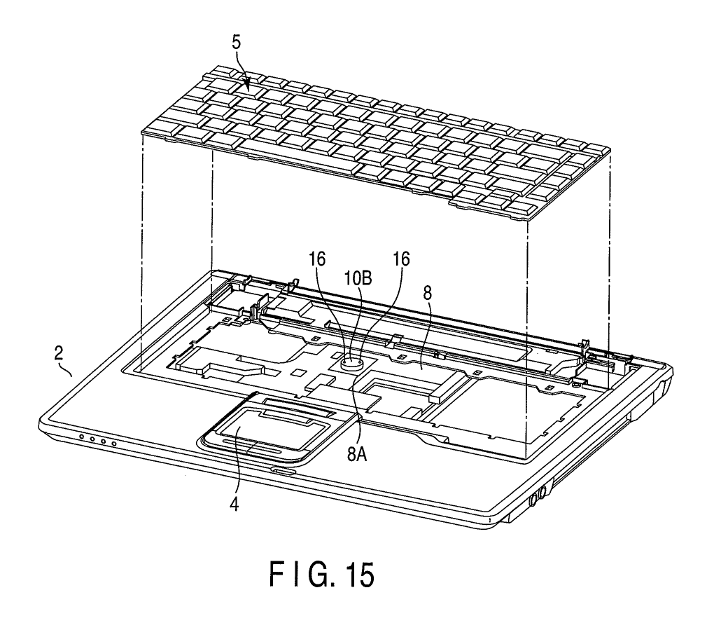

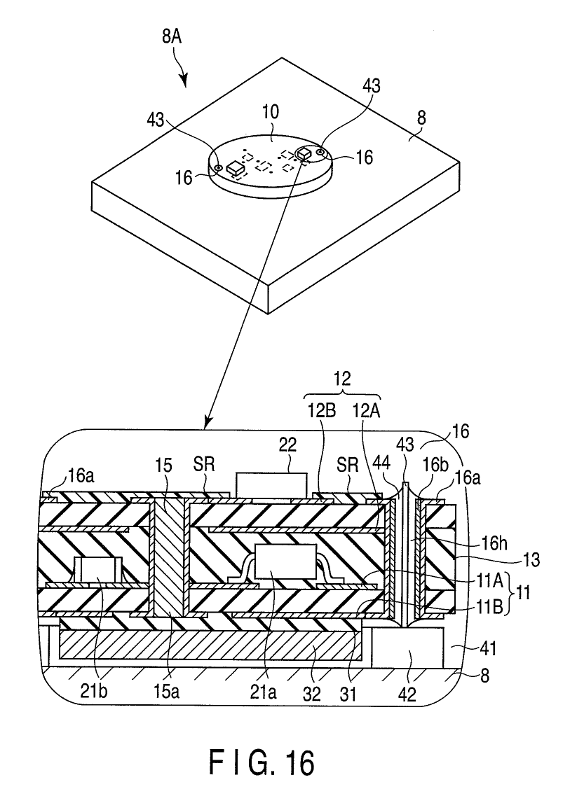

The second embodiment provides an electronic apparatus using a component-embedded printed circuit board 10 according to the first embodiment. In the present embodiment, a portable computer is used as an example of an electronic apparatus. FIG. 14 shows the configuration of the outside of the portable computer in the second embodiment. FIG. 15 shows the configuration of the inside of the portable computer from which some of its components (e.g., keyboard) shown in FIG. 14 have been removed. FIG. 16 shows the configuration of the main part 8A shown in FIG. 15.

A display housing 3 is attached to a main body 2 of the portable computer 1 so as to be freely rotatable via a hinge mechanism. Provided on the main body 2 are operating parts such as a pointing device 4 and keyboard 5. The display housing 3 has a display device 6 such as an LCD.

The main body 2 also includes a circuit board (i.e., motherboard) 8 incorporating a control circuit, which controls the operation parts (e.g., pointing device 4, keyboard 5) and the display device 6. A component-embedded printed circuit board 10 for use as a daughterboard (i.e., component-embedded printed circuit board) according to the first embodiment is mounted on this motherboard 8. As shown in FIGS. 1 and 2, the daughterboard includes: a first substrate 11; a second substrate 12 bonded to the first substrate 11 with an insulating layer 13 therebetween; built-in components 21a and 21b mounted on the component mounting surface, which is the inside conductor layer 11A of the first substrate 11, and covered by the insulating layer 13; openings H for member fixation formed in parts of the peripheral edge of the outer layer side of the first substrate 11; a metal member 32 for heat radiation laminated to the outer layer side (other than the openings H for member fixation) of the first substrate 11 with an insulating layer 31 therebetween; through-holes Ph penetrating the first and second substrates 11 and 12 and communicating with the corresponding openings H for member fixation; and through-hole conductors 16a and 16b forming a two-layer structure on the internal wall of each of the through-holes Ph.

As shown in FIG. 3, the motherboard 8 on which the component-embedded printed circuit board 10 is to be mounted has a daughterboard mounting member 41 in a daughterboard mounting area so as to correspond to the component-embedded printed circuit board 10 to be mounted. Each of the daughterboard connection electrodes 42 is provided on the daughterboard mounting member 41 so as to correspond to an external connection electrode 16. Further, a connection pin (lead terminal) 43 extends upward from the daughterboard connection electrode 42 so as to correspond to the through-hole 16h.

The process for mounting the component-embedded printed circuit board 10 on the motherboard 8 is described below. In the component mounting step, the through-hole 16h of the component-embedded printed circuit board 10 to be mounted is aligned to the connection pin 43 extending upward from the corresponding daughterboard connection electrode 42 on the daughterboard mounting member 41. Thereafter, the connection pin 43 is extended through the through-hole 16h, thereby placing the component-embedded printed circuit board 10 on the daughterboard mounting member 41. Subsequently, in a reflow step, molten solder 44 is caused to flow into the through-holes 16h. Consequently, the through-holes 16h are filled with the solder 44 and hence the connection pins 43 are soldered and joined to the corresponding through-holes 16h. Accordingly, the component-embedded printed circuit board 10 is mounted on the daughterboard mounting area of the motherboard 8, and is connected to the motherboard 8 in circuit via the external connection electrodes 16. In this circuit connection, each of the external connection electrodes 16 has an electrode structure in which the hole is bored perpendicular to the lamination. This ensures a connection area (i.e., solder joint face) sufficient for external connection, and hence a configuration of an external connection circuit assuring high reliability and stability. In addition, the electrode lead is formed from the through-hole conductors 16a and 16b forming a two-layer structure. This ensures a mounting and connecting structure in which the component-embedded printed circuit board 10 is rigidly fixed to the mounting mother body so that electric current flows easily. This assures high reliability of mounting and stability of circuit operation. The second embodiment exemplifies the configuration in which a component-embedded printed circuit board 10 that includes the external connection electrodes 16 having the through-hole structure is mounted on the motherboard 8. However, the second embodiment is not limited to this but, as shown in FIG. 4, the component-embedded printed circuit board 10 may be directly mounted on the electronic apparatus housing.

The embodiments of the invention described above in detail make it possible to realize a component-embedded printed circuit board provided with metal for heat radiation and having an external connection electrode of a through-hole form, a method of manufacturing the same, and an electronic apparatus including the same.

While certain embodiments of the inventions have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A component-embedded printed circuit board comprising:
a first substrate comprising a component mounting surface on an inner layer side of the first substrate;
a second substrate layered to the first substrate with an insulating layer between the first and second substrates;
a built-in component on the component mounting surface and under the insulating layer;
a concave portion on a peripheral edge of an outer layer side of the first substrate;
a metal portion configured to radiate heat, layered to an area on the outer layer side of the first substrate, excluding the concave portion, with an insulating layer between the first substrate and the metal portion;
a through-hole through the first and second substrates comprising an end on the concave portion; and
a through-hole conductor on an internal wall of the through-hole.

2. The component-embedded printed circuit board of claim 1, wherein the through-hole conductor is a cylindrical conductor.

3. The component-embedded printed circuit board of claim 2, wherein the cylindrical conductor is an electrode lead of an external connection electrode.

4. The component-embedded printed circuit board of claim 3, wherein an internal surface of the cylindrical conductor is a solder joint surface.

5. The component-embedded printed circuit board of claim 4, wherein the internal surface of the cylindrical conductor is a mounting hole through which an attaching component is configured to attach an external component.

6. The component-embedded printed circuit board of claim 5, wherein the cylindrical conductor comprises a metal-plated layer on the internal surface of the through-hole, and a conductive layer on the metal-plated layer.

7. The component-embedded printed circuit board of claim 1, wherein the concave portion is a notch in the metal portion.

8. The component-embedded printed circuit board of claim 2, wherein the first substrate comprises an outer-surface solid pattern layer on an outer layer side of the first substrate configured to conduct heat generated from the built-in component to the metal portion.

9. A method of manufacturing a component-embedded printed circuit board, comprising:
laminating a second substrate to a first substrate with an insulating layer between the first and second substrate and covering an electronic component on a component mounting surface of the first substrate with the insulating layer;
forming a through-hole through the first and second substrates in a direction perpendicular to the lamination;
embedding a conductor in the through-hole and drilling a hole in a portion of the conductor thereby forming a cylindrical through-hole conductor in the through-hole;
laminating a metal portion configured to radiate heat to an outer layer side of the first substrate with an insulating layer between the metal portion and the first substrate; and
forming a notch in the metal portion configured to radiate heat comprising the cylindrical through-hole conductor exposed from the notch to an atmosphere.

10. An electronic apparatus comprising:
a body; and
a component-embedded board in the body,
the component-embedded board comprising:
a first substrate comprising a component mounting surface on an inner layer side of the first substrate;
a second substrate layered to the first substrate with an insulating layer between the first and second substrates;
a built-in component on the component mounting surface and under the insulating layer;
a concave portion on a peripheral edge of an outer layer side of the first substrate;
a metal portion configured to radiate heat, layered to an area on the outer layer side of the first substrate, excluding the concave portion, with an insulating layer between the first substrate and the metal portion;
a through-hole through the first and second substrates comprising an end on the concave portion; and
a cylindrical through-hole conductor on an internal wall of the through-hole,
wherein the component-embedded substrate is attached on a substrate mounting portion of the body by an attaching component extending through a cylindrical hole of the cylindrical through-hole conductor.
